(19) United States
(12) Patent Application Publication
(10) Pub. No.: US 2021/0280452 A1
(43) Pub. Date: Sep. 9, 2021

(54) CREATING AN IMPLANTED LAYER IN A SILICON-ON-INSULATOR (SOI) WAFER THROUGH CRYSTAL ORIENTATION CHANNELING

(71) Applicant: QUALCOMM Incorporated, San Diego, CA (US)

(72) Inventors: Ravi Pramod Kumar VEDULA, San Diego, CA (US); Stephen Alan FANELLI, San Marcos, CA (US)

(21) Appl. No.: 16/809,796

(22) Filed: Mar. 5, 2020

(51) Int. Cl. H01L 21/762

(52) U.S. Cl. CPC H01L 21/76243

(57) ABSTRACT

Utilizing crystal orientation channeling through the semiconductor lattice structure of a silicon-on-insulator (SOI) wafer to create a thermally stable implanted amorphous layer beneath a buried oxide (BOX) layer in the SOI wafer is described. Utilizing channeling in this manner may involve tilting and/or twisting the SOI wafer to align axes of the crystal orientation channels with projections vectors from an implanter. One example method of fabricating a semiconductor device generally includes orienting an SOI substrate, the SOI substrate having a BOX layer and a device layer disposed above the BOX layer, such that directions of projection vectors from an implanter are substantially aligned with longitudinal axes of crystal orientation channels in a lattice structure of a semiconductor material of the device layer; and projecting, with the implanter, ions or particles into the crystal orientation channels of the oriented SOI substrate to create an implanted layer below the BOX layer.

### TECHNICAL FIELD

Certain aspects of the present disclosure generally relate to semiconductor devices and, more particularly, to methods of fabricating a semiconductor device with an implanted layer disposed below a buried oxide (BOX) layer in a silicon-on-insulator (SOI) substrate.

### BACKGROUND

Silicon-on-insulator (SOI) technology involves fabrication of silicon semiconductor devices in a layered silicon-insulator-silicon substrate. When compared to conventional silicon devices, the silicon junction of an SOI device is above an electrical insulator, typically silicon dioxide (SiO₂).

SOI technology, first commercialized in the late 1990s, represents an advance over traditional bulk silicon processes. The defining characteristic of SOI technology is that the semiconductor region in which circuitry is formed is isolated from the bulk substrate by an electrically insulating layer. One advantage of isolating circuitry from the bulk substrate is a dramatic decrease in parasitic capacitance, which allows access to a more desirable power-speed performance horizon. Therefore, SOI structures are particularly appealing for high-frequency applications, such as radio frequency (RF) communication circuits. As consumer demand continues to tighten the power constraints faced by RE communication circuits, SOI technology continues to grow in importance.

### SUMMARY

Certain aspects of the present disclosure generally relate to methods for fabricating a semiconductor device with a thermally stable implanted amorphous layer disposed under a buried oxide (BOX) layer of a silicon-on-insulator (SOI) substrate by utilizing crystal orientation channels in the lattice structure of the semiconductor material of a device layer to implant ions or particles in the SOI substrate.

Certain aspects of the present disclosure provide a method of fabricating a semiconductor device. The method generally includes orienting an SOI substrate, the SOI substrate having a BOX layer and a device layer disposed above the BOX layer, such that directions of projection vectors from an implanter are substantially aligned with longitudinal axes of crystal orientation channels in a lattice structure of a semiconductor material of the device layer; and projecting, with the implanter, ions or particles into the crystal orientation channels in the lattice structure of the semiconductor material of the device layer of the oriented SOI substrate to create an implanted layer below the BOX layer in the SOI substrate.

Certain aspects of the present disclosure provide a method of fabricating a semiconductor device. The method generally includes orienting an implanter such that projection vectors from the implanter will be substantially aligned with longitudinal axes of crystal orientation channels in a lattice structure of a semiconductor material of a device layer in an SOI substrate; and projecting, with the oriented implanter according to the projection vectors, ions or particles into the crystal orientation channels in the lattice structure of the semiconductor material of the device layer to create an implanted layer below a BOX layer disposed below the device layer in the SOI substrate.

Certain aspects of the present disclosure provide a method of fabricating a semiconductor device. The method generally includes orienting an SOI substrate, the SOI substrate having a BOX layer and a device layer disposed above the BOX layer, such that projection vectors from an implanter will be substantially aligned with a crystal orientation of a semiconductor material of the device layer; and projecting, with the implanter, ions or particles through the device layer of the oriented SOI substrate to create an implanted layer below the BOX layer in the SOI substrate.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a flow diagram of example operations for fabricating a semiconductor device, in accordance with certain aspects of the present disclosure.

FIGS. 2A-2C depict cross-sectional views of example operations for creating a thermally stable implanted amorphous layer beneath a buried oxide (BOX) layer in a silicon-on-insulator (SOI) substrate, in accordance with certain aspects of the present disclosure.

FIG. 3A is a model of a silicon (Si) crystal along the <110> direction, illustrating crystal orientation channels, in accordance with certain aspects of the present disclosure.

FIG. 3B is a model of the Si crystal of FIG. 3A in the <100> direction.

FIG. 4A conceptually illustrates tilt and twist of a projection beam with respect to a wafer, in accordance with certain aspects of the present disclosure.

FIG. 4B conceptually illustrates vertical implantation, in accordance with certain aspects of the present disclosure.

FIGS. 5A and 5B are example graphs illustrating higher concentrations of impurities of an implanted layer at greater depths due to utilizing crystal orientation channeling during the implantation, in accordance with certain aspects of the present disclosure.

Like reference numbers and designations in the various drawings indicate like elements.

### DETAILED DESCRIPTION

Certain aspects of the present disclosure generally relate to a process flow for creating an implanted layer (also known as a “trap rich layer”) beneath a buried oxide (BOX) layer in a silicon-on-insulator (SOI) wafer. Creating this implanted layer may be accomplished by utilizing crystal orientation channeling through the semiconductor lattice structure of a device layer above the BOX layer in the SOI wafer, thereby reducing damage to the device layer during the implantation. Utilizing channeling in this manner may involve tilting and/or twisting the SOI wafer to align longitudinal axes of the crystal orientation channels with projections vectors from an implanter.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### Example Implanted Layer Formation in a SOI Substrate

In general, SOI wafers with a high-resistivity handle can be used for radio frequency (RF) complementary metal-oxide-semiconductor (CMOS) transistor applications. However, implementations of such applications generally lack a trap rich layer because SOI wafers that include a trap rich layer are typically substantially more costly to produce than a standard SOI wafer.

Certain aspects of the present disclosure relate to using a high-resistivity SOI with an ultra-thin BOX and body (UTBB) layer and implanting carbon or other elements into the SOI to create a thermally stable implanted amorphous layer disposed below the BOX layer at decreased cost compared to the conventional trap rich layer SOI wafers.

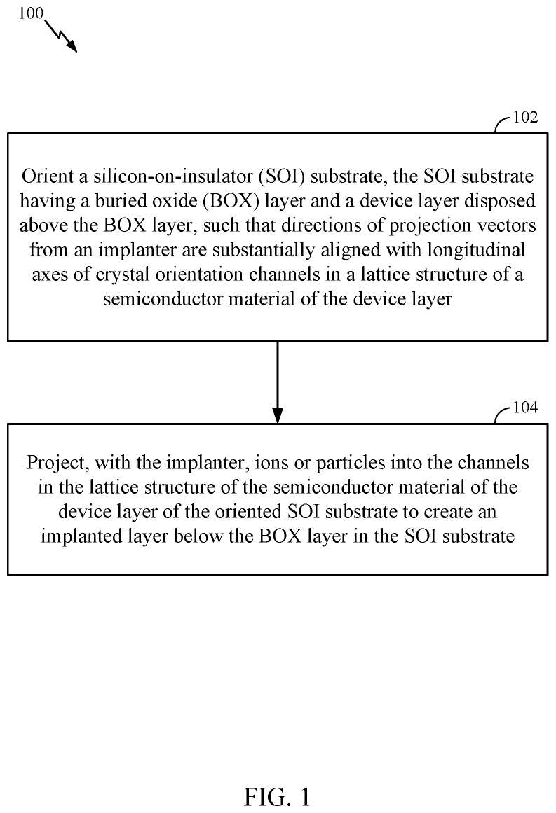

FIG. 1 is a flow diagram of example operations 100 for fabricating a semiconductor device, in accordance with certain aspects of the present disclosure. The operations 100 may be performed by a semiconductor fabrication facility (e.g., a foundry).

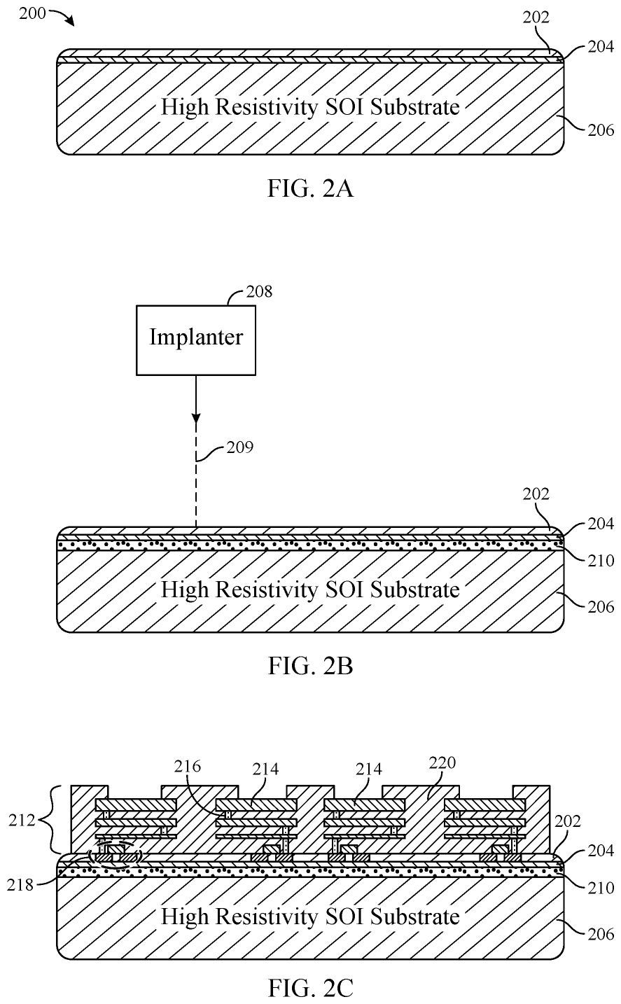

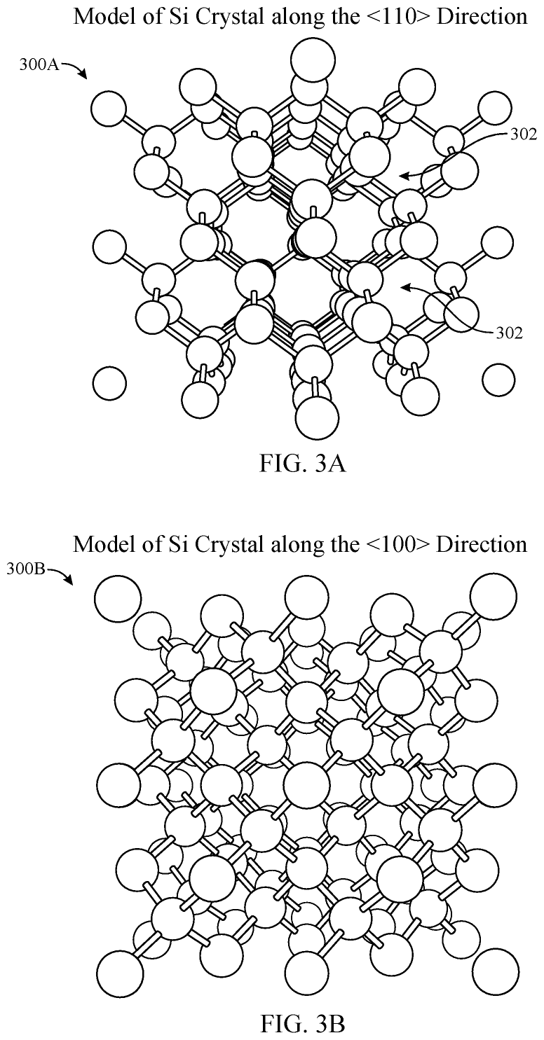

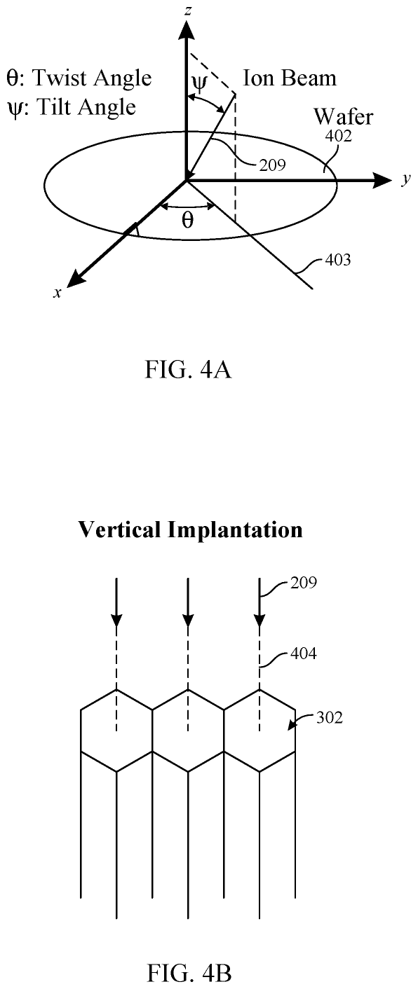

The operations 100 may begin at block 102 with the facility orienting an SOI substrate (e.g., a substrate 206 as described with respect to FIG. 2A). The SOI substrate may have a buried oxide (BOX) layer (e.g., BOX layer 204 as described with respect to FIG. 2A) and a device layer (e.g., device layer 202 as described with respect to FIG. 2A) disposed above the BOX layer. The facility may orient the SOI substrate such that directions of projection vectors (e.g., projection vector 209 as described with respect to FIG. 2B) from an implanter (e.g., implanter 208 as described with respect to FIG. 2B) are substantially aligned with longitudinal axes (e.g., longitudinal axes 404 as described with respect to FIG. 4B) of crystal orientation channels (e.g., crystal orientation channels 302 as described with respect to FIG. 3A) in a lattice structure of a semiconductor material (e.g., silicon (Si)) of the device layer. As used herein, being “substantially aligned” generally refers to two lines (e.g., a projection vector and a longitudinal axis) being collinear or forming an angle ≤±1°.

Aligning the longitudinal axes of the crystal orientation channels with the projection vectors makes projected ions or particles more likely to pass through the crystal orientation channels undeflected, thereby reducing damage to the device layer during the implantation. In one example, the implanter may be moved relative to a stationary SOI substrate for alignment. In another example, the SOI substrate may be moved (e.g., tilted and/or twisted) relative to a stationary implanter for alignment. In yet another example, both the implanter and the SOI substrate may be moved relative to one another, such that the projection vectors and the longitudinal axes of the crystal orientation channels may be substantially aligned.

At block 104, the facility projects, with the implanter, ions or particles into the crystal orientation channels in the lattice structure of the semiconductor material of the device layer of the oriented SOI substrate to create an implanted layer (e.g., implanted layer 210 as described with respect to FIG. 2B) below the BOX layer in the SOI substrate. The implanter may project the ions or particles according to the directions of the projection vectors.

The operations 100 may offer a low-cost method for fabricating an SOI substrate with an implanted layer. Furthermore, a layer transfer process need not be performed, no bonding need be employed, and an additional handle wafer need not be used in fabricating such an SOI substrate with an implanted layer.

FIG. 2A depicts a cross-sectional view of an example SOI substrate 200, in accordance with certain aspects of the present disclosure. The SOI substrate 200 may comprise a device layer 202, a BOX layer 204 disposed below the device layer 202, and a handle 206. Composed of silicon (Si), the device layer 202 is used for fabricating transistors and other electrical components in subsequent manufacturing steps. The BOX layer 204 may comprise any of various suitable oxides, such as silicon dioxide (SiO₂), and may span the entire width of the SOI substrate 200. The handle 206 may be a high-resistivity silicon handle, which may comprise lightly doped silicon to achieve high resistivity. Such a high-resistivity silicon handle may prevent, or at least reduce, crosstalk between electronic circuits formed in the device layer 202. Increasing the resistance of the handle reduces crosstalk by maintaining a relatively higher impedance of the parasitic paths through the handle.

Although high-resistivity handles are capable of reducing substrate loss when used in SOI processes, such handles are highly susceptible to another phenomenon referred to as “parasitic surface conduction.” Parasitic surface conduction is due to the fact that the lightly doped silicon that composes the handle can form an inversion or accumulation region as charge carriers are affected by signal voltages in the device layer. As a result, the capacitance of the junction between the handle and the device layer, as seen by the device layer, depends on the electric field emanating from the device layer and leads to nonlinearity. In addition, al electric field can invert this interface on the handle side and create a channel-like layer within a region underneath the BOX layer. In this channel-like layer, charge can move laterally very easily, despite the fact the handle is highly resistive. Therefore, this channel-like layer may also lead to crosstalk in certain applications (e.g., RF communication circuits). A solution to this undesirable creation of the channel-like layer underneath the BOX layer is to form a trap rich layer at the top of the handle. The presence of this trap rich layer effectively combats parasitic surface conduction because the trap rich layer significantly degrades the carrier lifetime of the charge carriers in the region underneath the BOX layer. Since the carriers cannot travel far, the effective resistance of the handle is preserved, and the capacitance seen by the device layer is not as dependent upon the signals in the device layer.

As illustrated in FIG. 2B, an implanter 208 (also referred to as a projector) may be used to project energetic ions or particles into the device layer 202 along one or more projection vectors 209. The projected ions or particles may travel through the crystal lattice structure of the semiconductor material of the device layer 202. The ions or particles that are not deflected by the device layer 202 may reach the BOX layer 204. The BOX layer 204 may randomly deflect the projected ions or particles to form an implanted layer 210 below the BOX layer. The implanted layer 210 may also be referred to as a trap rich layer, as described above. The projection energy used may range from 20 kilo-electronvolts (keV) to 200 keV, for example. Any of various suitable ions or particles for creating an implanted layer may be used, including carbon (C) ions, boron (B) ions, or oxygen (O), hydrogen (H), nitrogen (N), helium (He), argon (Ar), neon (Ne), xenon (Xe), or krypton (Kr) particles. If the dose of the ions or particles distributed by the BOX layer 204 meets or exceeds a critical dose, the implanted layer 210 may be amorphous. In this case, the implanted layer 210 may be considered as a thermally stable implanted amorphous layer.

Although the projection vector 209 is illustrated in FIG. 2B as being perpendicular to the plane of the SOI substrate 200, this may not be case. Rather, according to certain aspects of the present disclosure, the SOI substrate 200 and/or the direction(s) of the projection vector(s) 209 may be tilted and/or twisted to align the direction(s) of the projection vector(s) with crystal orientation channels in the silicon crystal lattice structure of the device layer 202, which are described below with respect to FIGS. 3A and 4B.

After forming the implanted layer 210 as illustrated in FIG. 2B, active devices (e.g., transistors) may be formed in the device layer 202, and then, front-end-of-line (FEOL) and back-end-of-line (BEOL) fabrication processes may be used to form an integrated circuit (IC) die, as shown in FIG. 2C. The IC die may be a radio frequency front-end (RFFE) IC, for example. For example, an active region 212 of the IC die may include transistors 218, metal layers 214, vias 216, and a dielectric material 220. Example transistors 218 may include n-type metal-oxide-semiconductor (NMOS) transistors, p-type metal-oxide-semiconductor (PMOS) transistors, bipolar junction transistors (BJTs), heterojunction bipolar transistors (HBTs), and the like.

FIGS. 3A-3B illustrate models of a silicon (Si) crystal lattice structure in different orientations, to show how at least one orientation may provide channels for projected ions or particles to pass through the lattice structure, whereas other orientations may not provide such atomic-level pathways through the lattice structure. With these channels, ions or particles projected into the Si crystal have a lower probability of striking a Si atom and being deflected, thereby reducing damage to the Si crystal during such projection for creating an implanted layer, as described above.

Specifically, FIG. 3A illustrates a model 300A of a Si crystal lattice structure viewed along the <110> direction (using Miller indices). When viewed with this orientation, the Si atoms form a lattice with crystal orientation channels 302. The crystal orientation channels 302 may have a hexagonal shape in the Si crystal lattice structure, and this shape extends through multiple layers of the Si crystal. The multiple layers being aligned and having similar shape provides crystal orientation channels 302 seen in the <110> direction of the model 300A.

In contrast, FIG. 3B illustrates a model 300B of the same Si crystal lattice structure, but viewed along the <100> direction (using Miller indices). When viewed with this orientation, the Si atoms do not appear to form atomic-level pathways through the lattice structure. In other words, there may not be crystal orientation channels 302 along the <100> direction of the model 300B as there are in the <110> direction. Thus, ions or particles traveling along the <100> direction through an SOI wafer are more likely to be deflected and damage the lattice structure than when traveling along the <110> direction.

The angle between the <100> directional view and the <110> directional view is 45°. Therefore, the orientation of the SOI wafer—and more particularly, the orientation of the Si crystal lattice structure in the device layer of the SOI wafer—with respect to the projection vectors of the ions or particles matters when creating an implanted layer beneath a BOX layer in the SOI wafer. For example, traveling through the crystal orientation channels 302 of the <110> directional view of the model 300A versus attempting to travel through the <100> directional view of the model 300B may cause less deflection of the ions or particles since the crystal orientation channels 302 in the <110> direction are larger than any perceived pathways in the <100> direction. In certain aspects, less deflection of particles may alter the distribution of particles, allowing implantation of impurities with greater depth in the implanted layer.

FIG. 4A conceptually illustrates tilt and twist (i.e., rotation) of a projection vector 209 (e.g., an ion beam from an implanter) relative to a wafer 402 (e.g., an SOI wafer) in accordance with certain aspects of the present disclosure. These concepts can also be applied to tilt and twist of a wafer with respect to a projection vector. The tilt angle may be defined as the angle between the projection vector 209 and an orthogonal projection from the center of the planar wafer 402 (e.g., the z-axis, also referred to as the “vertical axis”). The twist angle θ (also referred to as the “rotation angle”) may be defined as the angle between a reference axis on the planar wafer 402 (e.g., the x-axis) and a projection 403 of the projection vector 209 onto the planar wafer 402.

For certain aspects, the projection vector 209 may be tilted and/or twisted (i.e., rotated) with respect to the wafer 402, such that the projection vector is aligned with a crystal orientation channel in the lattice structure of the wafer. In this manner, the tilt angle and/or the twist angle θ of the projection vector 209 may effectively change the orientation of the semiconductor lattice structure of the wafer 402 and influence the amount of deflection projected particles or ions experience when traveling through the lattice structure. For example, tilting and/or rotating a projection vector 209 from an implanter 208 relative to an SOI wafer 200 as in FIG. 2B may change the tilt angle and/or the twist angle θ.

For other aspects, the wafer 402 may be tilted and/or twisted with respect to the projection vector 209 (which may be considered as the z-axis in this scenario), such that the projection vector is aligned with a crystal orientation channel in the lattice structure of the wafer. In this manner, the tilt angle and/or the twist angle θ of the wafer 402 may change the orientation of the semiconductor lattice structure from the perspective of the projection vector 209. For example, tilting and/or rotating an SOI substrate 200 relative to a projection vector 209 of an implanter 208 as in FIG. 2B may change the tilt angle and/or the twist angle θ.

The objective behind tilting and/or twisting the projection vector and/or the SOI substrate may be to achieve vertical implantation. As used herein, “vertical implantation” generally refers to projection vectors from an implanter being substantially aligned with longitudinal axes of crystal orientation channels in a semiconductor lattice structure (e.g., channels 302 along the <110> direction in a Si crystal).

FIG. 4B conceptually illustrates vertical implantation, in accordance with certain aspects of the present disclosure. In certain aspects, the crystal orientation channels 302 may be modeled as tubes (columns) having a hexagonal shape in cross-section, and each channel may have a longitudinal axis 404 (e.g., perpendicular to a center of the hexagonal cross-section), as illustrated in FIG. 4B. In certain aspects, the projection vectors 209 may be substantially aligned with (e.g., collinear to or within a certain tolerance of) the longitudinal axes 404 of the crystal orientation channels 302, as depicted. For example, the projection vectors 209 may be within ±1° of the longitudinal axes 404 of the crystal orientation channels 302 to achieve vertical implantation, thereby reducing damage to the device layer of the SOI substrate and achieving a higher concentration of impurities at greater depths, during creation of the implanted layer, compared to conventional trap rich layer implantation techniques.

Using parallel projection vectors 209 (parallel beams) as illustrated in FIG. 4B may provide for taking advantage of channeling (vertical implementation) across the entire SOI substrate. This is in contrast to using electrostatic deflection of the beam, where the advantages of channeling may be realized only at and near the center of the SOI substrate. For other aspects, the SOI substrate may be moved (e.g., mechanically scanned) with respect to parallel beams (or possibly steered beams) covering only a portion of the surface of the SOI substrate to eventually accomplish vertical implantation over the entire surface of the SOI substrate.

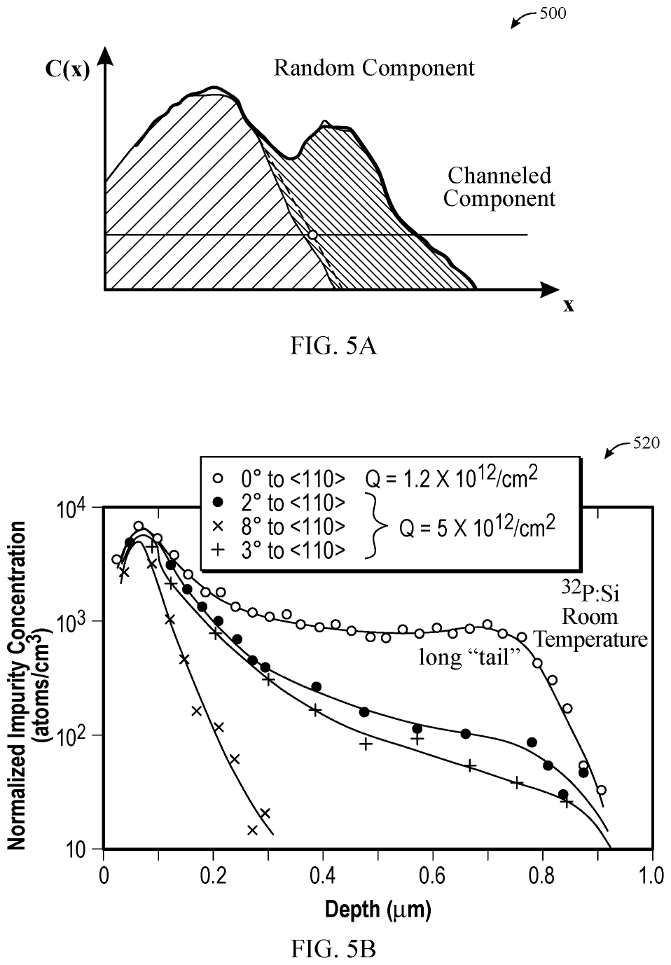

FIGS. 5A and 5B are example graphs illustrating higher concentrations of impurities of an implanted layer at greater depths due to utilizing crystal orientation channeling during the implantation

FIG. 5A is an example graph 500 illustrating higher concentrations of impurities of an implanted layer at greater depths due to utilizing crystal orientation channeling during the implantation, in accordance with certain aspects of the present disclosure. The y-axis of the graph 500 represents an impurity concentration C(x) due to projected ions or particles, and the x-axis represents depth x. The left portion of the graph 500 illustrates a random component of the concentration i.e., a component of the concentration due to random distribution), whereas the right portion of the graph 500 illustrates a channeled component (i.e., a component of the concentration due to the crystal orientation channeling). The channeled component may be generated by vertically implanting ions or particles into the SOI substrate 200 by orienting the SOI substrate 200 and substantially aligning the projection vectors 209 and the longitudinal axes 404 of the crystal orientation channels 302 through the SOI substrate 200. In certain aspects, vertical implantation in this manner may lead to a higher concentration of impurities at greater depths and may reduce impurities and damage in the device layer.

FIG. 5B is an example graph 520 of normalized impurity concentration (in atoms/cm³) versus depth (in μm) for different alignment angles, in accordance with certain aspects of the present disclosure. As shown, the tilt angle relative to the <110> direction of FIGS. 4A and 3A may be changed. Such change may produce various concentration distributions. For example, a tilt angle ψ of 0° may provide a concentration distribution with a long tail with relatively higher concentrations of ions or particles extending as deep as 0.9 μm. This long tail may correspond to the channeled component as described above with respect to the graph 500 of FIG. 5A. As shown, a tilt angle ψ of 2° may provide a concentration distribution with a tail; however, even though the concentrations of ions or particles may extend as deep as 0.9 μm for a concentration above 10 atoms/cm³, the impurity concentration distribution from 0.2 to 0.9 μm may not be as high for 2° compared to that for 0°. Similarly, a tilt angle ψ of 3° may provide a concentration distribution with a tail; however, even though the concentrations of ions or particles may extend as deep as 0.9 μm for a concentration above 10 atoms/cm³, the concentration distribution for 3° between 0.2 to 0.9 μm may be lower compared to that of 0° and 2°. As shown, a tilt angle ψ of 8° may provide a concentration distribution with a short tail that extends to approximately 0.3 μm for a concentration above 10 atoms/cm³. A tilt angle ψ of 8° may create a concentration distribution of particles or ions that ranges between 0.0 to 0.3 μm. This concentration distribution for a tilt angle ψ of 8° may correspond to the random component as described above with respect to the graph 500 of FIG. 5A.

Returning to FIG. 1, orienting the SOI substrate at block 102 may involve tilting a plane of the SOI substrate (e.g., substrate 200 or the planar wafer 402) with respect to the directions of the projection vectors (e.g., projection vectors 209). The orienting may further comprise twisting the SOI substrate.

In certain aspects, the orienting at block 102 may entail aligning the directions of the projection vectors within ±1° of the longitudinal axes (e.g., longitudinal axes 404) of the crystal orientation channels (e.g., crystal orientation channel 302) in the lattice structure (e.g., model 300A) of the device layer (e.g., device layer 202).

In certain aspects, the projecting at block 104 may comprise vertical implantation of the ions or particles (e.g., FIG. 4B), such that a plane of the SOI substrate (e.g., substrate 200 or the planar wafer 402) is tilted with respect to vertical projections of the ions or particles from the implanter.

In certain aspects, the ions or particles may comprise carbon (C) ions or boron (B) ions. In other aspects, the ions or particles may comprise oxygen (O), hydrogen (H), or nitrogen (N) particles. In other aspects, the ions or particles may comprise noble gas molecules, such as helium (He), argon (Ar), neon (Ne), xenon (Xe), or krypton (Kr).

In certain aspects, the BOX layer may scatter the projected ions or particles to create the implanted layer. For example, the projected ions or particles may be scattered to have a particular concentration distribution (e.g., FIG. 5A or 5B).

In certain aspects, no layer transfer or bonding may be performed, for example, to create a trap rich SOI wafer.

In certain aspects, the SOI substrate may comprise an ultra-thin BOX and body (UTBB) substrate.

In certain aspects, the SOI substrate may further comprise a high-resistivity silicon handle disposed beneath the BOX layer.

In certain aspects, the thermally stable implanted amorphous layer is generated at a depth between 10 angstroms (Å) and 4000 Å from a bottom surface of the BOX layer.

In certain aspects, the projecting at block 104 involves projecting with an implantation energy of at least 20 keV (or 30 keV) and less than 200 keV. In certain aspects, the operations 100 may accommodate higher energies extending to, for example, 4 MeV.

According to certain aspects, the projecting at block 104 entails projecting the ions or particles with parallel beams.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation, and details of the methods and apparatus described above without departing from the scope of the claims.

1. A method of fabricating a semiconductor device, comprising:
orienting a silicon-on-insulator (SOI) substrate, the SOI substrate having a buried oxide (BOX) layer and a device layer disposed above the BOX layer, such that directions of projection vectors from an implanter are substantially aligned with longitudinal axes of crystal orientation channels in a lattice structure of a semiconductor material of the device layer; and
projecting, with the implanter, ions or particles into the crystal orientation channels in the lattice structure of the semiconductor material of the device layer of the oriented SOI substrate to create an implanted layer below the BOX layer in the SOI substrate.

2. The method of claim 1, wherein the orienting comprises tilting a plane of the SOI substrate with respect to the directions of the projection vectors.

3. The method of claim 2, wherein the orienting further comprises twisting the SOI substrate.

4. The method of claim 1, wherein the orienting comprises aligning the directions of the projection vectors within ±1° of the longitudinal axes of the crystal orientation channels in the lattice structure.

5. The method of claim 1, wherein the projecting comprises vertical implantation of the ions or particles, such that a plane of the SOI substrate has a tilt angle with respect to vertical projections of the ions or particles from the implanter.

6. The method of claim 1, wherein the ions or particles comprise carbon (C) ions or boron (B) ions.

7. The method of claim 1, wherein the ions or particles comprise oxygen (O), hydrogen (H), or nitrogen (N) particles.

8. The method of claim 1, wherein the ions or particles comprise helium (He), argon (Ar), neon (Ne), xenon (Xe), or krypton (Kr) particles.

9. The method of claim 1, wherein the BOX layer scatters the projected ions or particles to create the implanted layer.

10. The method of claim 1, wherein the implanted layer becomes amorphous when a concentration of the projected ions or particles exceeds a critical dose.

11. The method of claim 1, wherein the implanted layer comprises a thermally stable implanted amorphous layer.

12. The method of claim 1, wherein no layer transfer or bonding is performed to create a trap rich SOI wafer.

13. The method of claim 1, wherein the SOI substrate further comprises a high-resistivity silicon handle disposed beneath the BOX layer.

14. The method of claim 1, wherein the implanted layer is generated at a depth between 10 Å and 4000 Å from a bottom surface of the BOX layer.

15. The method of claim 1, wherein the projecting comprises projecting with an implantation energy of at least 30 keV and less than 200 keV.

16. The method of claim 1, wherein the projecting comprises projecting the ions or particles with parallel beams.

17. A method of fabricating a semiconductor device, comprising:
orienting an implanter such that projection vectors from the implanter will be substantially aligned with longitudinal axes of crystal orientation channels in a lattice structure of a semiconductor material of a device layer in a silicon-on-insulator (SOI) substrate; and
projecting, with the oriented implanter according to the projection vectors, ions or particles into the crystal orientation channels in the lattice structure of the semiconductor material of the device layer to create an implanted layer below a buried oxide (BOX) layer disposed below the device layer in the SOI substrate.

18. The method of claim 17, wherein the orienting comprises aligning directions of the projection vectors within ±1° of the longitudinal axes of the crystal orientation channels in the lattice structure.

19. The method of claim 17, wherein the projecting comprises vertical implantation of the ions or particles, such that the projection vectors from the implanter have a tilt angle with respect to an orthogonal projection from a plane of the SOI substrate.

20. The method of claim 17, wherein the ions or particles comprise carbon (C) ions.
